(19) United States
(12) Patent Application Publication
(10) Pub. No.: US 2001/0031517 A1
(43) Pub. Date: Oct. 18, 2001

(54) Process for fabrication of split-gate virtual phase charge coupled devices

(76) Inventor: Jaroslav Hynecek, Richardson, TX (US)

Correspondence Address: Alan K. Stewart, Texas Instruments Incorporated, P.O. Box 655474, MS 3999, Dallas, TX, 75265, US

(21) Appl. No.: 09/728,261

(22) Filed: Dec. 1, 2000

Related U.S. Application Data
(60) Provisional application No. 60/173,231, filed on Dec. 28, 1999.

(51) Int. Cl. H01L 21/339

(52) U.S. Cl. 438/144

(57) ABSTRACT

The method for making a virtual phase charge coupled device with multi-directional charge transfer capabilities includes: forming a semiconductor region 48 of a first conductivity type; forming first gate regions 32 and 36 overlying and separated from the semiconductor region 48; forming second gate regions 34 and 38 adjacent to the first gate regions 32 and 36 and electrically separated from the first gate regions 32 and 36; forming virtual gate regions 24, 26, and 28 of a second conductivity type in the semiconductor region 48 and aligned to the gate regions 32, 34, 36, and 38.

### FIELD OF THE INVENTION

This invention generally relates to charge coupled devices, and more particularly relates to split-gate virtual phase charge coupled devices.

### BACKGROUND OF THE INVENTION

Without limiting the scope of the invention, its background is described in connection with charge coupled device (CCD) image sensors, as an example. A typical CCD consists of several gate levels (usually polysilicon) which are used to control the potential within the silicon bulk. By applying suitable bias to the gates, the potential is modulated which in turn causes charge transfer. Virtual phase CCD was developed to minimize the number of polysilicon levels. This resulted in many advantages such as better quantum efficiency and lower dark current (elimination of surface state component of the dark current). In the virtual phase CCD one polysilicon level has been eliminated and replaced by a P+ junction. This P+ junction region is connected to the substrate through an undepleated channel stop region. Virtual phase CCD can be characterized by alternative placement of a MOS structure with JFET structures in a coupled chain. By clocking the MOS gates charge is Transferred, while the JFET region potential is fixed. The potential steps which provide the necessary directionality for the charge transfer are usually created by a suitable ion implantation. It is not necessary to connect the virtual phase region to the substrate through the channel stops. Other methods are possible. See for example “Method of Making Top Buss Virtual Phase Frame Interline Transfer CCD Image Sensor”, U.S. Pat. No. 5,151,380.

### SUMMARY OF THE INVENTION

Generally, and in one form of the invention, a method for making a virtual phase charge coupled device with multidirectional charge transfer capabilities includes: forming a semiconductor region of a first conductivity type; forming first gate regions overlying and separated from the semiconductor region; forming second gate regions adjacent to the first gate regions and electrically separated from the first gate regions; forming virtual gate regions of a second conductivity type in the semiconductor region and aligned to the gate regions.

### BRIEF DESCRIPTION OF THE DRAWINGS

In the drawings:

FIG. 1 is a plan view of the preferred embodiment virtual phase charge coupled device (CCD) structure with two-directional charge transfer capability;

FIG. 2 is a cross-section of the device of FIG. 1;

FIG. 3 is a cross-section of the device of FIG. 1;

FIG. 4 is a clocking scheme for shifting charge from left to right in the device of FIG. 2;

FIG. 5 is a clocking scheme for shifting charge from right to left in the device of FIG. 2;

FIGS. 6 and 7 show the device of FIG. 2 at two stages of fabrication;

FIG. 8 is a cross-section of the preferred embodiment virtual phase CCD with a self-aligned antiblooming structure;

FIG. 9 is an alternative embodiment virtual phase CCD structure with two-directional charge transfer capability.

Corresponding numerals and symbols in the different figures refer to corresponding parts unless otherwise indicated.

### DETAILED DESCRIPTION OF PREFERRED EMBODIMENTS

There is a need for a CCD image sensor where charge can be transported in several directions. Standard virtual phase CCD sensors with only a single polysilicon gate and a directional well implant under it does not allow such a transfer. To accomplish two-directional or four-directional transfer capability, a modification to the design of the structure of the prior art standard virtual phase CCD device is needed.

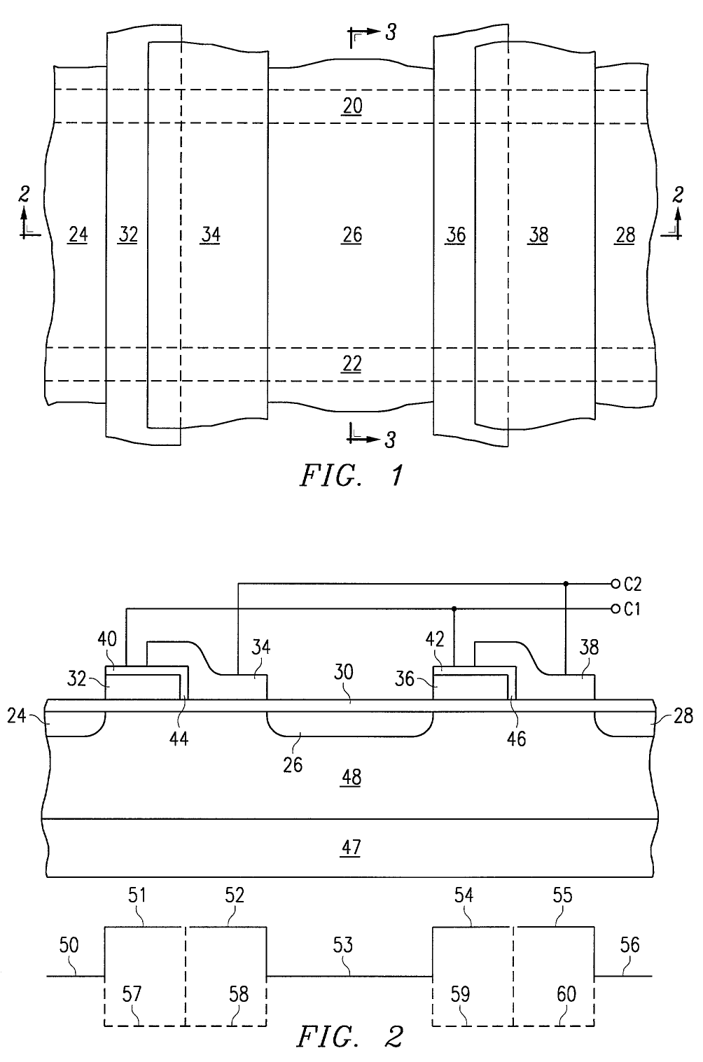

FIG. 1 is a plan view of a preferred embodiment virtual phase charge coupled device (CCD) structure with two-directional charge transfer capability. The device of FIG. 1 includes P+ channel stop regions 20 and 22; P+ virtual gate regions 24, 26, and 28; gate regions (polysilicon) 32, 34, 36, and 38. FIG. 2 is a cross-section of the device of FIG. 1. The structure of FIG. 2 includes a P type semiconductor layer 47; N type semiconductor region 48; P+ virtual gates 24, 26, and 28; insulator layer (gate oxide) 30, patterned gate regions (polysilicon) 32, 34, 36, and 38; insulator regions (oxide) 40, 42, 44, and 46; clock signals C1 and C2; and potential levels 50-60. FIG. 3 is a cross-section of the device of FIG. 1. The structure of FIG. 3 includes P type semiconductor layer 47; N type semiconductor region 48; P+ virtual gate 26; gate oxide 30; and P+ channel regions 20 and 22.

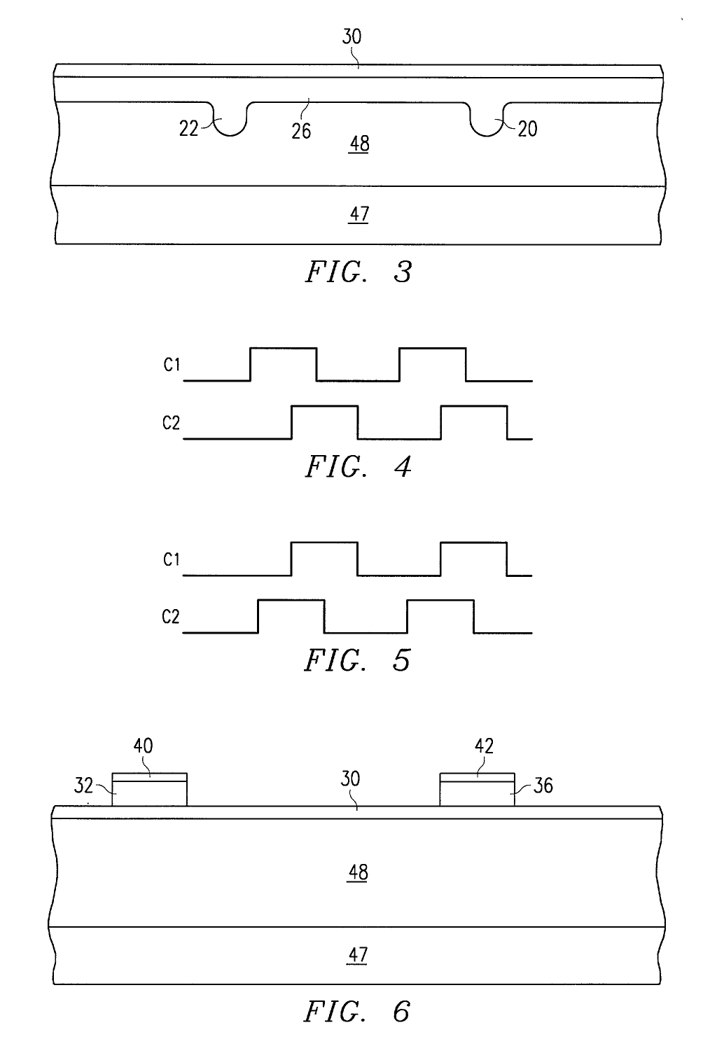

To transfer charge from left to right in FIG. 2, the clocking scheme shown in FIG. 4 is used. Starting with clock signals C1 and C2 both at low levels, clock signal C1 is switched high. Then clock signal C2 is switched high. Next, clock signal C1 is switched low followed by clock signal C2 being switched low. This clock sequence shifts the charge one virtual gate to the right. To transfer charge from right to left, the clocking scheme shown in FIG. 5 is used. Starting with clock signals C1 and C2 both at low levels, clock signal C2 is switched high. Then clock signal C1 is switched high. Next, clock signal C2 is switched low followed by clock signal C1 being switched low. This clock sequence shifts the charge one virtual gate to the left.

FIGS. 6 and 7 illustrate successive steps in a process for fabricating the virtual phase CCD according to the preferred embodiment, as shown in FIG. 2. Referring first to FIG. 6, the process begins with a silicon layer 47 of P type conductivity. Then phosphorus is implanted and annealed to form N type region 48. Gate oxide layer 30 is then grown by oxidation to the desired thickness, for example, about 1000 angstroms. Next, a layer of polysilicon is deposited over the oxide and doped to be conductive. For the polysilicon layer, from 500 to 5000 Angstroms of polysilicon is deposited. The polysilicon layer may be doped in place by a dopant such as phosphorus. A layer of oxide is then formed over the polysilicon layer and densified. The oxide layer and polysilicon layer are patterned and etched to form patterned gate regions 32 and 36, and oxide regions 40 and 42.

Then, referring to FIG. 7, the gate regions 32 and 36 are laterally oxidized. This lateral oxidation is preferably performed at a low temperature such as 850-900 degrees C in order to not increase the thickness of gate oxide 30 significantly. Since the gate regions 32 and 36 are phosphorus doped to a high level, the oxide regions 44 and 46 on the sides grow much faster than on the silicon substrate (as much as 10 times faster). Next, another polysilicon layer is deposited and etched to form gate regions 34 and 38. Then virtual gate regions 24, 26, and 28 are formed by phosphorus implants and shallow boron implants with lateral diffusion control between phosphorus and boron. Various annealing steps and diffusions can be easily used to control the potential profile at the interface between the clocked gates and the virtual gates. The P+ channel stop regions 20 and 22, shown in FIGS. 1 and 3, are formed by a first P type implant before the polysilicon layers are deposited, and a second P type implant after polysilicon gates 32, 34, 36, and 38 are formed. After the above steps, interlevel oxide and metalization are formed using standard procedures. P+ source/drains (not shown) are formed before the interlevel oxide and metalization.

A self-aligned antiblooming structure, is also incorporated into the above process, as shown in FIG. 8. The structure of FIG. 8 includes a P type semiconductor layer 47; N type semiconductor region 48; P+ virtual gates 62 and 64; insulator layer (gate oxide) 30, patterned gate regions (polysilicon) 66, 68, and 70; doped region 72; and N+ antiblooming drain 74. This structure can be formed from either the first or second polysilicon layer. In the following description, the first polysilicon layer is used. During patterning and etching of gate regions 32 and 36, antiblooming gate 70 is formed in the shape of a ring. Boron is implanted into the center of the ring 70 and diffused laterally to form region 72. Long diffusion at higher temperatures is acceptable since no other doping accept the buried channel 48 is present in the structure during this step. Then N+ antiblooming drain 74 is implanted and annealed. At the same time, N+ drains (not shown) can be implanted into the rest of the circuit.

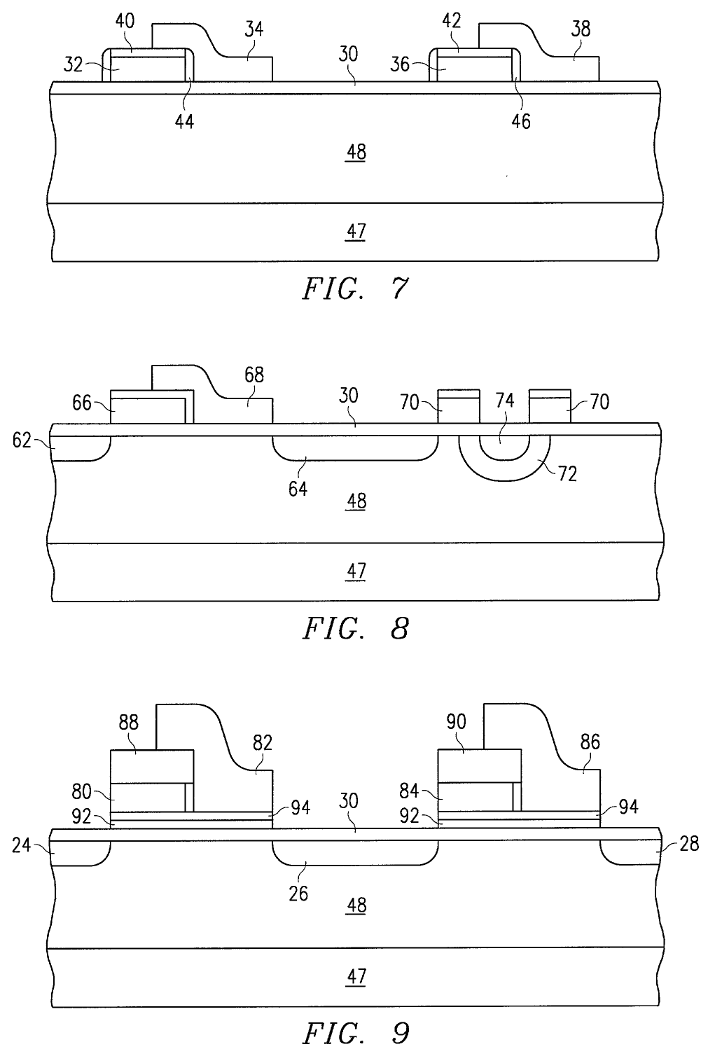

An alternative embodiment, shown in FIG. 9, reduces the capacitance between polysilicon gates 80 and 82, and between polysilicon gates 84 and 86 by using thick oxide regions 88 and 90 (on the order of 2000 angstroms). Nitride layer 92 and oxide layer 94 are necessary for growing the thick oxide layer that forms oxide regions 88 and 90. Polysilicon regions 80 and 84 are formed on the order of 1000 angstroms thick. Polysilicon regions 82 and 86 are formed on the order of 3000 angstroms thick.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. It is therefore intended that the appended claims encompass any such modifications or embodiments.

What is claimed is:

1. A method for making a virtual phase charge coupled device with multi-directional charge transfer capabilities comprising:
forming a semiconductor region of a first conductivity type;
forming first gate regions overlying and separated from the semiconductor region;
forming second gate regions adjacent to the first gate regions and electrically separated from the first gate regions;
forming virtual gate regions of a second conductivity type in the semiconductor region and aligned to the gate regions.

2. The method of claim 1 further comprising, before forming the gate regions, forming a gate insulator layer over the semiconductor region.

3. The method of claim 1 further comprising, before forming the second gate regions, forming insulator regions over the first gate regions.

4. The method of claim 1 further comprising, forming an antiblooming structure adjacent to one of the virtual gate regions.

5. The method of claim 4 wherein a method of making the antiblooming structure comprises:
forming an antiblooming gate region overlying the semiconductor region and having an opening in the antiblooming gate region;
forming a doped region of the second conductivity type in the semiconductor region below the opening in the antiblooming gate region; and
forming an antiblooming drain of the first conductivity type in the doped region.

6. The method of claim 1 wherein the first conductivity type is N type.

7. The method of claim 1 wherein the second conductivity type is P type.

8. The method of claim 1 wherein the gate regions are polysilicon.

9. The method of claim 2 wherein the gate insulator layer is oxide.

10. The method of claim 3 wherein the insulator regions are oxide.

11. The method of claim 1 wherein the semiconductor region is formed in a semiconductor layer of the second conductivity type.
